(19) United States
(12) Patent Application Publication
(10) Pub. No.: US 2010/0141263 A1
(43) Pub. Date: Jun. 10, 2010

(54) SYSTEM AND METHOD FOR TESTING AN IMAGE SENSOR USING GRADATION IMAGE CAPTURE

(76) Inventor: Fumiki Nakamura, Webster, NY (US)

Correspondence Address: Pedro P. Hernandez;Patent Legal Staff, Eastman Kodak Company, 343 State Street, Rochester, NY, 14650-2201, US

(21) Appl. No.: 12/331,637

(22) Filed: Dec. 10, 2008

(51) Int. Cl. G01R 31/00

(52) U.S. Cl. 324/501; 324/96

(57) ABSTRACT

A gradation image capture is used to test one or more image sensors. The integration periods for the rows of pixels in the array, or for groups of rows of pixels, are varied during each single still frame image capture. The S rows of pixels are reset either simultaneously or successively to a predetermined level, and then begin accumulating charges. The rows of pixels, or groups of rows of pixels, are read out at different times to vary the integration periods of the pixels. Some or all of the signals are analyzed or measured to detect any design or manufacturing problems.

### TECHNICAL FIELD

The invention relates generally to the field of image sensors, and more particularly to a system and method for testing an image sensor. Still more particularly, the invention relates to a system and method for testing an image sensor using gradation image capture.

### BACKGROUND

A typical electronic image sensor includes a number of light sensitive picture elements (“pixels”) arranged in a two-dimensional array. Multiple image sensors can be constructed on a single semiconductor wafer as part of the fabrication process. The image sensors are subsequently cut from the wafer to produce separate individual image sensors. As part of the fabrication process, the multiple image sensors are tested prior to being separated from the semiconductor wafer to detect design or manufacturing problems.

One testing method requires the pixels in an image sensor to capture a number of images, typically between ten and one hundred images. The integration period, or amount of time all of the pixels in the image sensor are allowed to capture an image, is changed for each captured image. For example, the integration period can initially be short for the first captured image and then increase as each subsequent image is captured. The images are analyzed to detect different design or manufacturing problems. A disadvantage to this testing method can be the high number of images that must be captured and analyzed, thereby increasing the amount of time needed to complete the test.

Another conventional but specialized testing method uses a gradation chart, such as the chart shown in FIG. 1. The gradation chart 100 has region dependent transmittance, meaning the darker regions 102 allow less light to pass through chart 100 compared to the lighter regions 104. FIG. 2 is a graphical illustration of a system 200 for testing an image sensor that uses gradation chart 100. Light source 202 emits light 204 that propagates through gradation chart 100 and towards wafer 206. An image sensor 208 on wafer 206 captures an image using filtered light 210 transmitted through gradation chart 100. Thus, an image sensor 208 is able to capture an image having different signal levels in a single image capture. Gradation chart 100 can typically be removed to allow different gradation charts to be used.

Unfortunately, testing system 200 requires an operator either add and remove the gradation chart from system 200 for each sample, or obtain two or more sets of samples using the same gradation chart. Current test systems do not have the capability for automatic addition and removal of gradation chart 100. And finally, a gradation chart may have transmittance sample-to-sample variations that can result in correlation errors between test systems.

### SUMMARY

The present invention uses a gradation image capture to test one or more image sensors. The integration periods for the rows of pixels in the array, or for groups of rows of pixels, are varied during each single still frame image capture. The rows of pixels are reset either simultaneously or successively to a predetermined level. The pixels then begin accumulating charges. The rows of pixels, or groups of rows of pixels, are then read out at different times to vary the integration periods of the pixels. Some or all of the signals are analyzed or measured to detect any design or manufacturing problems. The analysis can include, for example, a display of the captured image showing the gradation levels and a vertical profile of data from one or more output channels.

### ADVANTAGEOUS EFFECT OF THE INVENTION

The present invention includes the advantage of a still frame gradation image capture that varies the integration periods of the pixels during image capture. With a still frame gradation image capture testing system, different operational or performance parameters of an image sensor can be tested and measured. This allows for the detection of design or manufacturing problems in as few as one captured gradation image. The time and expense of testing and correcting defective designs or manufacturing problems is reduced, while the reliability and accuracy of the test is increased.

### BRIEF DESCRIPTION OF THE DRAWINGS

FIG. 1 is a top view of a gradation chart in accordance with the prior art;

FIG. 2 is a graphical illustration of a system for testing an image sensor that uses gradation chart 100;

FIG. 3 is a schematic diagram of a pixel that can be implemented in an image sensor in an embodiment in accordance with the invention;

FIG. 4 is a block diagram of a top view of an image sensor in an embodiment in accordance with the invention;

FIG. 5 is a flowchart of a first method for testing an image sensor using gradation image capture in an embodiment in accordance with the invention;

FIG. 6 is an exemplary timing diagram that can be utilized with the first method shown in FIG. 5;

FIG. 7 is an alternate exemplary timing diagram that can be utilized with the first method shown in FIG. 5;

FIG. 8 is a flowchart of a second method for testing an image sensor using gradation image capture in an embodiment in accordance with the invention;

FIG. 9 is an exemplary timing diagram that can be utilized with the second method shown in FIG. 8;

FIG. 10 is a simplified illustration of a system for testing an image sensor in an embodiment in accordance with the invention;

FIG. 11 depicts a display screen displaying a set of test results for a non-defective image sensor in an embodiment in accordance with the invention;

FIG. 12 illustrates a display screen displaying a set of test results for a defective image sensor in an embodiment in accordance with the invention;

FIG. 13 depicts a display screen displaying a more detailed view of pixelized temporal noise in an embodiment in accordance with the invention;

FIG. 14 illustrates a display screen displaying a more detailed view of row temporal noise in an embodiment in accordance with the invention; and

FIG. 15 depicts a display screen displaying a more detailed view of column temporal noise in an embodiment in accordance with the invention.

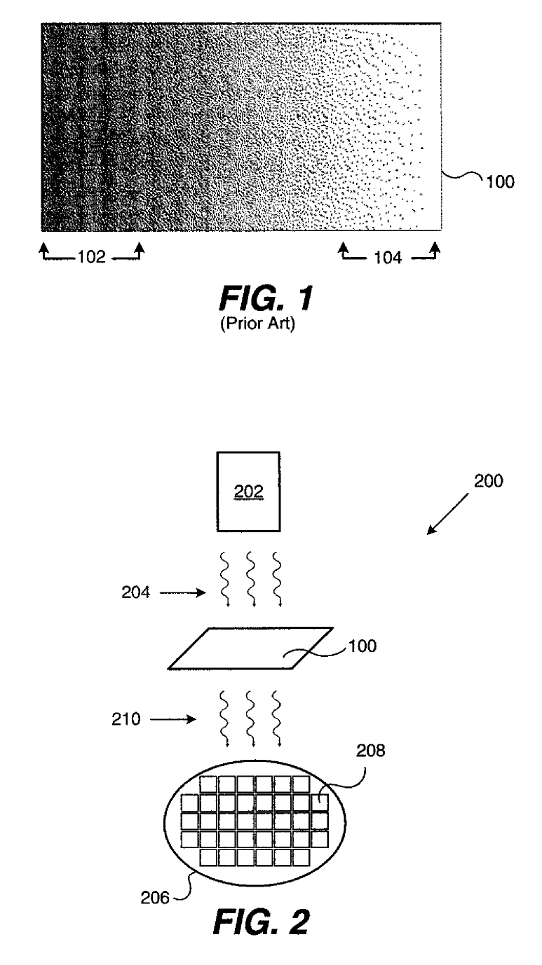

### DETAILED DESCRIPTION

Throughout the specification and claims, the following terms take the meanings explicitly associated herein, unless the context clearly dictates otherwise. The meaning of “a,” “an,” and “the” includes plural reference, the meaning of “in” includes “in” and “on.” The term “connected” means either a direct electrical connection between the items connected or an indirect connection through one or more passive or active intermediary devices. The term “circuit” means either a single component or a multiplicity of components, either active or passive, that are connected together to provide a desired function. The term “signal” means at least one current, voltage, or data signal. Referring to the drawings, like numbers indicate like parts throughout the views.

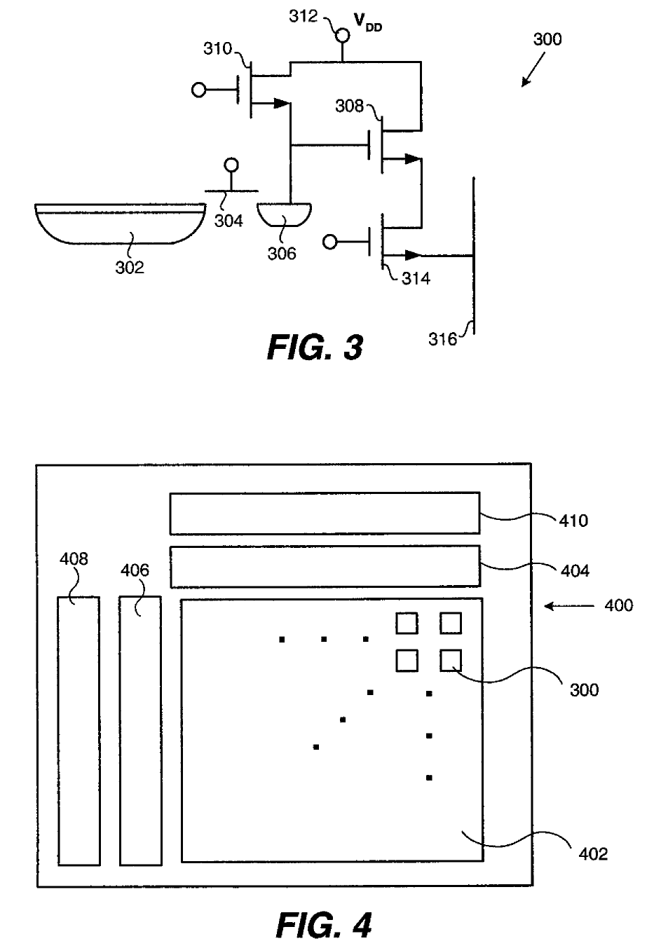

Referring now to FIG. 3, there is shown a schematic diagram of a pixel that can be implemented in an image sensor in an embodiment in accordance with the invention. Pixel 300 includes photodetector 302, transfer gate 304, charge-to-voltage conversion mechanism 306, amplifier 308, reset transistor 310, potential V_{DD} 312, and row select transistor 314, whose drain is connected to the source of amplifier 308 and whose source is connected to output 316. The drains of reset transistor 310 and amplifier 308 are maintained at potential V_{DD} 312. The source of reset transistor 310 and the gate of amplifier 308 are connected to charge-to-voltage conversion mechanism 306.

Photodetector 302 converts light into an electrical charge in response to light striking photodetector 302. The amount of charge generated by photodetector 302 depends on the amount of light that falls on photodetector 302, in terms of both intensity and duration. The amount of time photodetector 302 generates charge while exposed to light is known as an exposure period. The period of time between pixel reset and pixel readout is known as an integration period.

Reset transistor 310 resets pixel 300 by setting charge-to-voltage conversion mechanism 306 to potential V_{DD} 312. At the end of an integration period for photodetector 302, the accumulated charge is transferred to charge-to-voltage conversion mechanism 306 using transfer gate 304. Charge-to-voltage conversion mechanism 306 converts the charge into a voltage. Charge-to-voltage conversion mechanism 306 is configured as a floating diffusion in an embodiment in accordance with the invention.

Amplifier 308 amplifies the voltage in charge-to-voltage conversion mechanism 306. Amplifier 308 is implemented as a source follower transistor in an embodiment in accordance with the invention. Row select transistor 314 is used to select a row of pixels. When row select transistor 314 is active, the voltage on amplifier 308 is transferred to output 316 and subsequently read out from the pixel array and the image sensor. Pixels in other embodiments in accordance with the invention may be implemented differently from pixel 300. By way of example only, a pixel may omit one or more elements, such as charge-to-voltage conversion mechanism 306, in other embodiment in accordance with the invention.

FIG. 4 is a block diagram of a top view of an image sensor in an embodiment in accordance with the invention. Image sensor 400 includes pixel array 402 that includes multiple pixels 300 (FIG. 3) arranged in rows and columns, column decoder 404, row decoder 406, digital logic 408, and analog or digital output channels 410. Image sensor 400 is implemented as an x-y addressable image sensor, such as, for example, a Complementary Metal Oxide Semiconductor (CMOS) image sensor, in an embodiment in accordance with the invention. Thus, column decoder 404, row decoder 406, digital logic 408, and analog or digital output channel 410 are implemented as standard CMOS electronic circuits that are operatively connected to pixel array 402. Those skilled in the art will recognize that other peripheral circuitry configurations or architectures can be implemented in other embodiments in accordance with the invention.

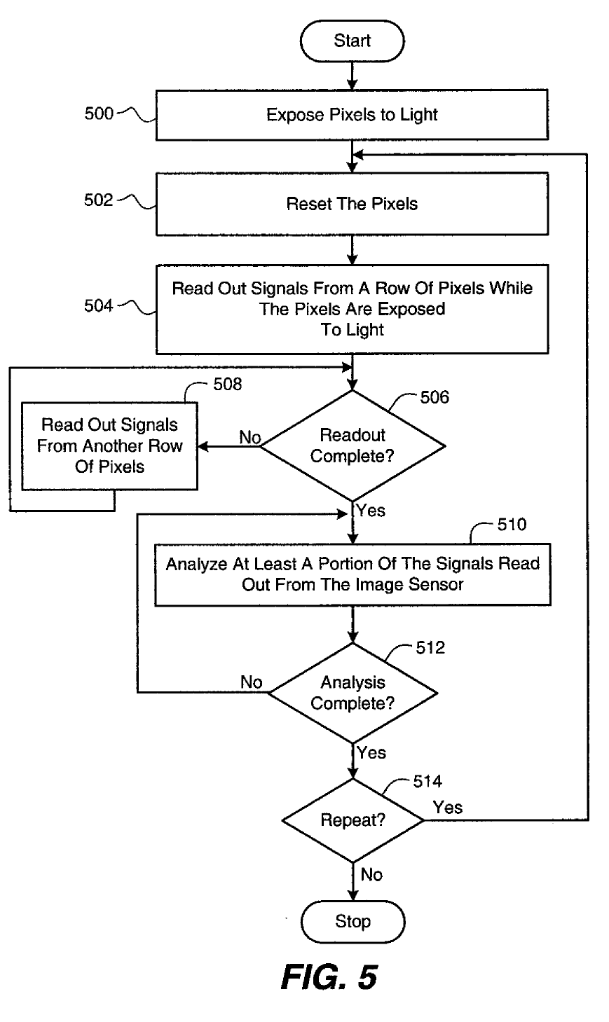

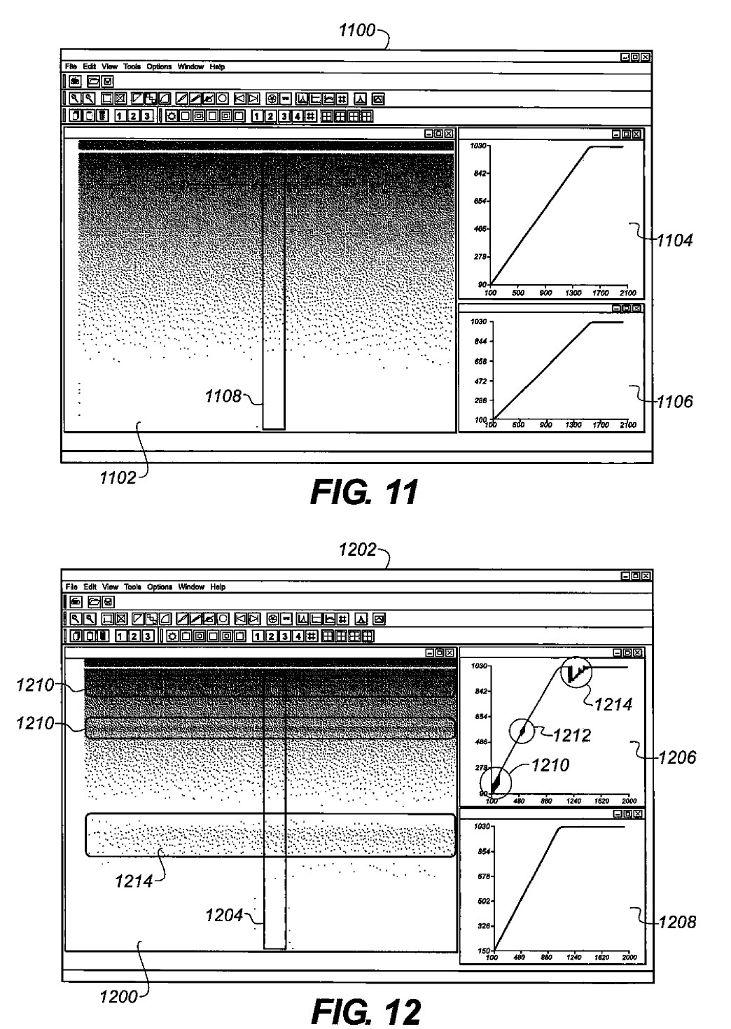

Referring now to FIG. 5, there is shown a flowchart of a first method for testing an image sensor using gradation image capture in an embodiment in accordance with the invention. Initially, the pixels are exposed to light, as shown in block 500. The pixels are then reset to a predetermined signal level (block 502) and the photodetectors begin accumulating charge. The accumulated charges are read out from a row of pixels on at least a row-by-row basis while the pixels are exposed to light. For example, the rows of pixels are read out one row at a time to vary the integration period of each row in an embodiment in accordance with the invention. Thus, the photodetectors in the first row of pixels that are read out have the shortest integration period while the photodetectors in the last row of pixels that are read out have the longest integration period. This results in a gradation image capture that will be discussed in more detail in conjunction with FIGS. 11 and 12. Those skilled in the art will recognize the rows can be read out in any order.

In another embodiment in accordance with the invention, the rows of pixels in the array are divided into distinct groups of rows of pixels with each group containing two or more rows of pixels. The groups can include the same number of rows in each group or vary the number of rows in one or more groups. The pixels in the groups are then read out one group at a time in an embodiment in accordance with the invention, resulting in a gradation image capture. Again, the groups of rows can be read out in any order.

Referring back to FIG. 5, a determination is then made at block 506 as to whether all of the pixels in the array have been read out. If not, the pixels in another row or groups of rows are read out (block 508) and the process returns to block 506. The signals can be read out of all of the pixels in the array, or read out of some of the pixels in the array in embodiments in accordance with the invention.

When all of the signals have been read out of the desired pixels in the array, some or all of the signals are analyzed (block 510). The analysis can include measurements or tests for various operational or performance parameters for the image sensor being tested. For example, the analysis can measure temporal noise signal level dependence or fixed pattern noise (FPN) signal level dependence. Alternatively, the analysis can determine the linearity of the image sensor.

A determination is then made at block 512 as to whether or not the analysis is complete. If not, the method returns to block 510. When the analysis is complete, a determination is made as to whether or not the process is to repeat (block 514). If the method is to repeat, the process returns to block 502 and repeats a given number of times.

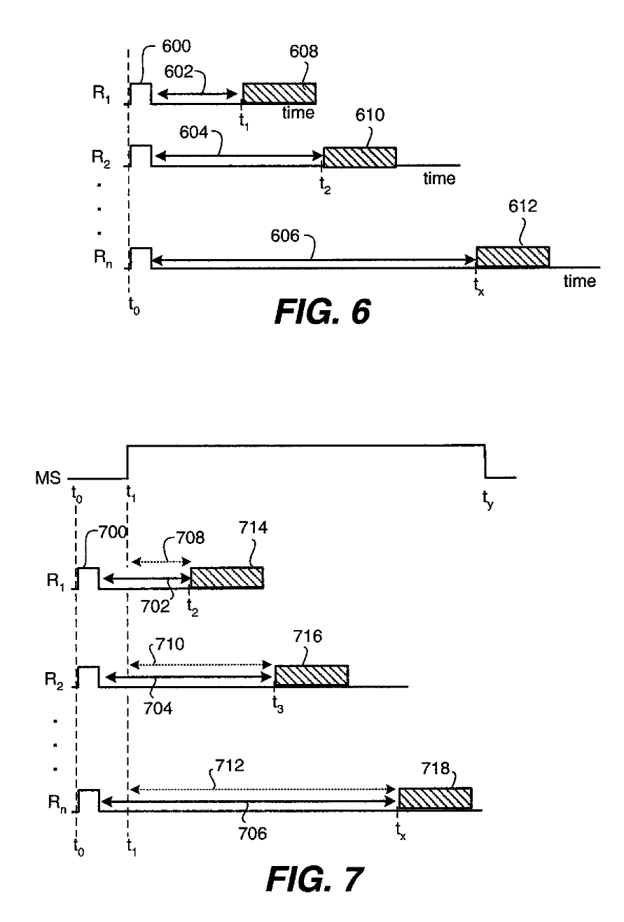

FIG. 6 is an exemplary timing diagram that can be utilized with the first method shown in FIG. 5. This exemplary timing diagram can be implemented in an image sensor that does not have a mechanical shutter. The pixels are continuously exposed to light in this embodiment in accordance with the invention.

All of the pixels in the array are simultaneously reset 600 at time to. The simultaneous reset 600 is implemented as a global reset in an embodiment in accordance with the invention. After the reset operation 600, the photodetectors in the rows of pixels R₁, R₂, Rₙ accumulate charges during their respective integration periods 602, 604, 606. R₁ represents the first row of pixels and Rₙ the last row of pixels in the array in an embodiment in accordance with the invention.

After a period of time, the accumulated charges or signals from the first row of pixels R₁ are read out 608 at time t₁ while the pixels in the other rows R₂ through Rₙ continue to accumulate charge. Some time later, the signals in the second row of pixels R2 are read out 610 at time t₂ while the pixels in the rows through row Rₙ continue to accumulate charge. Because row R₂ is read out after R₁, the integration period 604 of row R₂ is longer than the integration period 602 of row R₁. Thus, the amount of charges accumulated by the pixels in row R₂ is greater than the amount of charges accumulated by the pixels in row R₁.

The process of successively reading out the signals in a row of pixels one row at a time continues until the signals in row Rₙ are read out 612 at time tₓ. Because the read out times for the rows of pixels are varied over time, the integration periods 602, 604, 606 for the rows of pixels are different. This allows for a gradation image capture to be obtained in a single capture.

Referring now to FIG. 7, there is shown an alternate exemplary timing diagram that can be utilized with the first method shown in FIG. 5. This alternate exemplary timing diagram can be implemented in an image sensor that has a mechanical shutter. R₁ represents the first row of pixels and Rₙ the last row of pixels in the array in an embodiment in accordance with the invention.

The mechanical shutter (MS) is closed when the pixels in the array are simultaneously reset at time to. The integration periods 702, 704, 706 for the photodetectors in the rows of pixels R₁, R₂, Rₙ, respectively, begin after the reset operation 700. At time t₁ the mechanical shutter (MS) is opened and the pixels in the array are exposed to light. This begins the respective exposure periods 708, 710, 712 for the rows of pixels R₁, R₂, Rₙ.

After a period of time, the accumulated charges or signals in the first row of pixels R₁ are read out 714 at time t₂ while the pixels in the other rows R₂ through Rₙ continue to accumulate charge. Some time later, the signals in the second row of pixels R₂ are read out 716 at time t₃ while the pixels in the rows R₃ through Rₙ continue to accumulate charge. Because row R₂ is read out after R₁, the integration period 704 of row R₂ is longer than the integration period 702 of row R₁. Thus, the amount of charges accumulated by the pixels in row R₂ is greater than the amount of charges accumulated by the pixels in row R₁.

The process of successively reading out a row of pixels one row at a time continues until the signals in row Rₙ are read out 718 at time tₓ. The mechanical shutter (MS) is closed after time tₓ, at time t_{y}. The integration periods 702, 704, 706 for each row of pixels are different because the read out times for each row is varied over time. This allows for a gradation image capture to be obtained in a single capture.

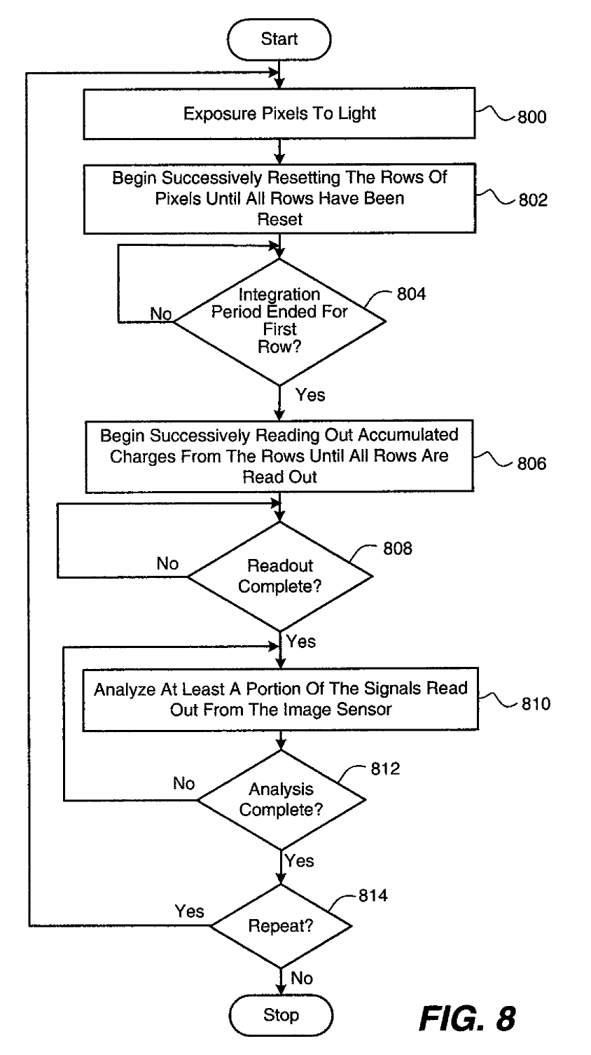

FIG. 8 is a flowchart of a second method for testing an image sensor using gradation image capture in an embodiment in accordance with the invention. Initially, the pixels in the array are exposed to light, as shown in block 800. The process of successively resetting each row of pixels, or groups of rows of pixels, to a predetermined signal level begins at block 802. This process continues until all of the rows or groups of rows have been reset. A determination is then made at block 804 as to whether or not the integration period for the first row of pixels, or the first group of rows of pixels, has ended. If not, the method waits until the integration period has ended.

When the integration period for the first row of pixels, or the first group of rows of pixels has ended, the process passes to block 806 where the process of successively reading out the accumulated charges or signals from the photodetectors in the row or group of rows of pixels begins. This process continues until all of the rows or groups of rows have been readout. A determination is then made at block 808 as to whether or not the readout process is complete. If not, the method waits until all of the desired pixels have been read out.

Some or all of the signals that are read out of the image sensor are then analyzed, as shown in block 810. The analysis can include measurements or tests for various operational or performance parameters for the image sensor being tested. For example, the analysis can measure temporal noise signal level dependence or fixed pattern noise (FPN) signal level dependence. Alternatively, the analysis can determine the linearity of the image sensor.

A determination is then made at block 812 as to whether or not the analysis of the signals is complete. If not, the method returns to block 810. When the analysis is complete, a determination is made at block 814 as to whether or not the method is to repeat. The process returns to block 800 when the method is to repeat.

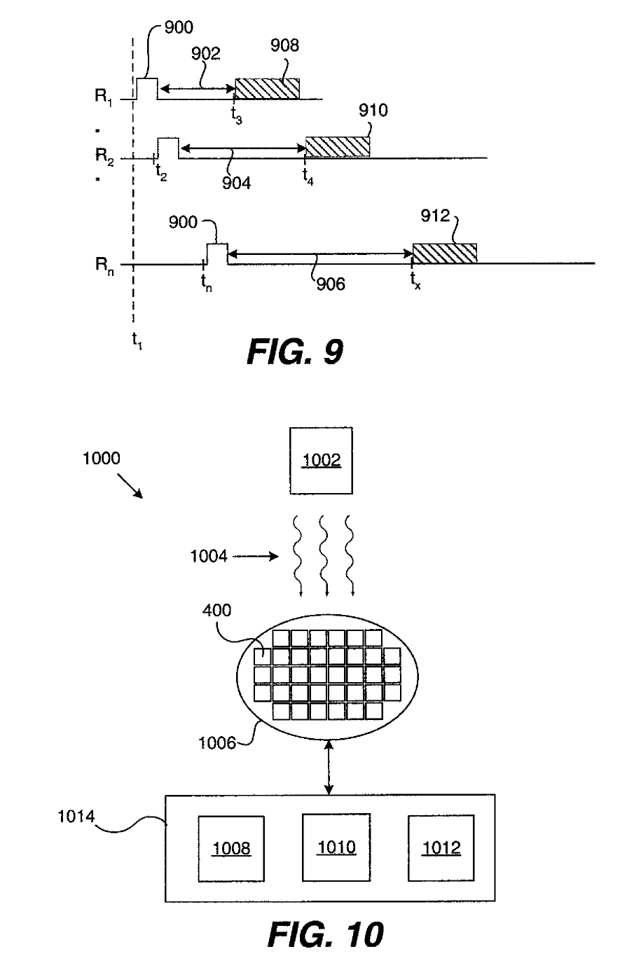

Referring now to FIG. 9, there is shown an exemplary timing diagram that can be utilized with the second method shown in FIG. 8. This exemplary timing diagram can be implemented in an image sensor that does not have a mechanical shutter and utilizes an electronic rolling shutter reset mechanism. R₁ represents the first row of pixels and Rₙ the last row of pixels in the array in an embodiment in accordance with the invention.

The first row of pixels R₁ in the array are reset 900 at time t₁. After the reset operation, the photodetectors in row R₁ accumulate charges during integration period 902. After a period of time, the second row of pixels R₂ is reset at time t₂. The photodetectors in row R₂ then accumulate charges during integration period 904. And finally, after a period of time, the last row of pixels Rₙ is reset at time tₙ and the photodetectors in row Rₙ accumulate charges during integration period 906.

The accumulated charges or signals in the first row of pixels R₁ are read out 908 at time t₃, while the pixels in the other rows R₂ through Rₙ continue to accumulate charges. Some time later, at time t₄, the signals in the second row of pixels R₂ are read out 910 while the pixels in the rows through row Rₙ continue to accumulate charges. Because integration period 904 for row R₂ is longer than integration period 902 for row R₁, the amount of charges accumulated by the pixels in row R₂ is greater than the amount of charges accumulated by the pixels in row R₁.

The process of successively reading out the signals in a row of pixels one row at a time continues until the signals in row Rₙ are read out 912 at time tₓ. Because the integration periods for the rows of pixels have varied lengths of time, a gradation image capture is obtained in a single capture. In other embodiments in accordance with the invention, the rows of pixels are divided into distinct groups of rows of pixels with each group containing two or more rows of pixels. The groups can include the same number of rows in each group or vary the number of rows in one or more groups. The pixels in the groups are then successively read out one group at a time to produce a gradation image capture. Again, the groups of rows can be read out in any order.

Referring now to FIG. 10, there is shown a simplified illustration of a system for testing an image sensor in an embodiment in accordance with the invention. Test system 1000 includes light source 1002 for emitting light 1004 towards semiconductor wafer 1006. A number of image sensors 400 (FIG. 4) have been fabricated on wafer 1006. Controller 1008 is used to generate the signals needed to cause the photodetectors in one or more of the image sensors 400 to begin accumulating charges. Controller 1008 also generates the signals needed to cause the accumulated charges to be readout of the pixels in the one or more image sensors 400 in a manner that varies the integration periods of the photodetectors in the sensor or sensors. For example, the pixels can be read out pursuant to the methods depicted in FIGS. 5 through 9. Controller 1008 may also be used to control light source 1002 in embodiments in accordance with the invention.

Processing unit 1010 is used to analyze the signals read out from each tested image sensor. Output device 1012 outputs the results of the analysis. Output device 1012 is implemented as a display in one embodiment in accordance with the invention, but can be configured differently in other embodiments in accordance with the invention. Controller 1008, processing unit 1010, and output device 1012 are included in a testing apparatus 1014 in an embodiment in accordance with the invention.

FIG. 11 is an illustration of a display screen displaying a set of test results for a non-defective image sensor in an embodiment in accordance with the invention. Screen 1100 includes three windows 1102,1104, 1106. Window 1102 displays the image captured by an image sensor. The captured image is a gradation image depicting the different levels of signals from the accumulated charges obtained by varying the integration periods of the rows of pixels in the image sensor. As shown in FIG. 11, the top portion of window 1102 displays the rows of pixels that had the shortest integration periods. Moving towards the bottom of window 1102, the image becomes lighter because the integration periods for the rows increased.

A selector 1108 is used to select one or more columns of pixels in window 1102 for more detailed views. Windows 1104, 1106 display vertical profiles of data for two readout or output channels in the image sensor. A vertical profile is created by sunning the signals of the pixels in each row in selector 1108 that is associated with a respective output channel in the image sensor. By changing the width of selector 1108, the size of the vertical profile can be made to be as small as a single column of pixels. As shown in windows 1104, 1106, both vertical profiles have uninterrupted linear slopes over the entire range of signals (e.g., dark to saturation) for the selected column or columns of pixels 1108.

Additional test results or data can be generated and output in other embodiments in accordance with the invention.

Referring now to FIG. 12, there is shown an illustration of a display screen displaying a set of test results for a defective image sensor in an embodiment in accordance with the invention. Window 1200 in screen 1202 displays the image captured by an image sensor. Selector 1204 has selected one or more columns of pixels in window 1208 for more detailed views. Window 1206 displays a vertical profile of data for one output channel while window 1208 displays a vertical profile of data for another output channel. The vertical profile in window 1208 has an uninterrupted linear slope over the entire range of signals for the selected column or columns 1204. The vertical profile in window 1206, however, depicts three areas 1210, 1212, 1214 that represent unacceptable levels of noise. These test results can be used, for example, to identify design or manufacturing problems associated with the pixels or output channels that may then be corrected.

FIGS. 13-15 depict display screens displaying more detailed views of pixelized, row, and column temporal noise, respectively. FIG. 13 shows the pixelized temporal noise data from two images that were consecutively captured using a gradation image capture technique that varies the integration periods of the rows of pixels during image capture. Areas 1300, 1302, and 1304 illustrate both green output channels (Gr and Gb) having a higher noise around each signal level than that of the red and blue output channels.

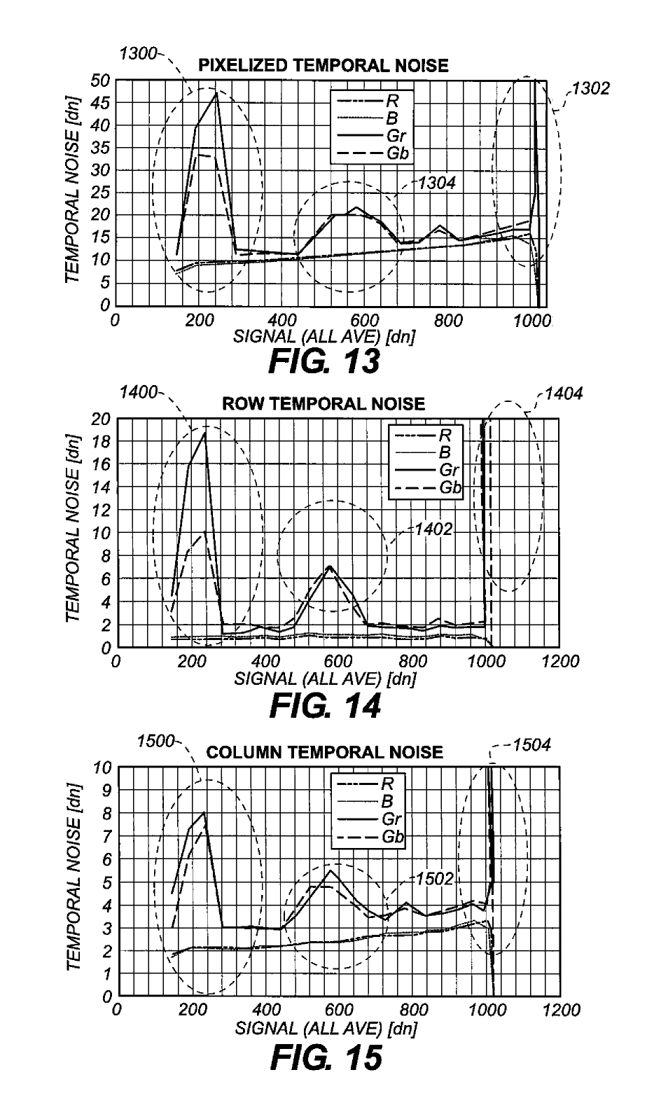

FIG. 14 illustrates the row temporal noise data from two images that were consecutively captured using a gradation image capture technique that varies the integration periods of the rows of pixels during image capture. Areas 1400, 1402, and 1404 illustrate both green output channels (Gr and Gb) having a higher noise around each signal level than that of the red and blue output channels.

And finally, FIG. 15 illustrates the column temporal noise data from two images that were consecutively captured using a gradation image capture technique that varies the integration periods of the rows of pixels during image capture. Areas 1500, 1502, and 1504 illustrate both green output channels (Gr and Gb) having a higher noise around each signal level than that of the red and blue output channels.

### Parts List

100 gradation chart
102 darker region
104 lighter region
200 testing system
202 light source
204 light
206 wafer
208 image sensor
210 filtered light
300 pixel
302 photodetector
304 transfer gate
306 charge-to-voltage conversion mechanism
308 amplifier
310 reset transistor
312 potential V_{DD}
314 row select transistor
316 output
400 image sensor
402 pixel array
404 column decoder
406 row decoder
408 digital logic
410 output channel
600 reset
602 integration period
604 integration period
606 integration period
608 read out
610 read out
612 read out
700 reset
702 integration period
704 integration period
706 integration period
708 exposure period
710 exposure period
712 exposure period
714 read out
716 read out
718 read out
900 reset
902 integration period
904 integration period
906 integration period
908 read out
910 readout
912 read out
1000 testing system
1002 light source
1004 light
1006 wafer
1008 controller
1010 processing unit
1012 output device
1014 testing apparatus
1100 display screen
1102 window
1104 window
1106 window
1108 selector
1200 window
1202 display screen
1204 selector
1206 window
1208 window
1210 noise area
1212 noise area
1214 noise area
1300 noise area
1302 noise area
1304 noise area
1400 noise area
1402 noise area
1404 noise area
1500 noise area
1502 noise area
1504 noise area

1. A method for testing an x-y addressable image sensor comprising a plurality of pixels that are arranged in rows and columns to form an array, wherein each pixel includes a photodetector, the method comprising:
exposing the plurality of pixels to light; and
varying an amount of time a row of photodetectors accumulates charges on at least a row-by-row basis while the plurality of pixels are exposed to light.

2. The method of claim 1, further comprising the step of analyzing at least a portion of signals read out of the x-y addressable image sensor.

3. The method of claim 1, further comprising the step of resetting the plurality of pixels to a predetermined signal level prior to varying an amount of time a row of photodetectors accumulates charges on at least a row-by-row basis.

4. The method of claim 3, wherein the step of resetting the plurality of pixels to a predetermined signal level comprises simultaneously resetting the plurality of pixels to a predetermined signal level.

5. The method of claim 3, wherein the step of resetting the plurality of pixels to a predetermined signal level comprises successively resetting each row of pixels to a predetermined signal level.

6. The method of claim 2, further comprising the step of repeating a predetermined number of times the steps of exposing the plurality of pixels to light, varying an amount of time a row of photodetectors accumulates charges on at least a row-by-row basis while the plurality of pixels are exposed to light, and analyzing at least a portion of the signals read out of the x-y addressable image sensor.

7. The method of claim 1, wherein the step of varying an amount of time a row of photodetectors accumulates charges on at least a row-by-row basis while the plurality of pixels are exposed to light comprises reading out signals from the rows of photodetectors in the array at different times and on a row-by-row basis to vary integration periods of the photodetectors in the array.

8. The method of claim 1, wherein the step of varying an amount of time a row of photodetectors accumulates charges on at least a row-by-row basis while the plurality of pixels are exposed to light comprises reading out signals from the rows of photodetectors in the array at different times and by distinct groups of rows of pixels to vary integration periods of the photodetectors in each distinct group of rows in the array.

9. The method of claim 2, wherein the step of analyzing at least a portion of the signals read out of the image sensor comprises generating a vertical image profile of one or more columns of pixels in the array.

10. The method of claim 9, further comprising the step of outputting the vertical image profile of one or more columns of pixels in the array to an output device.

11. The method of claim 9, wherein the step of generating a vertical image profile of one or more columns of pixels in the array comprises generating a vertical image profile of two or more columns of pixels in the array.

12. The method of claim 11, further comprising the step of summing on a row-by-row basis the signals read out of the pixels in the two or more columns of pixels.

13. The method of claim 1, wherein the step of analyzing at least a portion of the signals read out of the image sensor comprises generating a gradation image of the signals generated by the plurality of pixels in the array.

14. The method of claim 13, further comprising the step of outputting the gradation image of the signals generated by the plurality of pixels in the array to an output device.

15. A system for testing an x-y addressable image sensor comprised of a plurality of pixels arranged in rows and columns to form a array, wherein each pixel includes a photodetector, the system comprising:
a controller for generating signals to cause the plurality of pixels in the array to be exposed to light and to read out signals from the array on at least a row-by-row basis while the plurality of pixels are exposed to light to vary integration periods of the photodetectors in the array; and
a processing unit for analyzing at least a portion of the signals read out of the x-y addressable image sensor.

16. The system of claim 15, further comprising a light source.

17. The system of claim 15, wherein the controller generates signals to read out signals from the array on a row-by-row basis while the plurality of pixels are exposed to light to vary integration periods of the photodetectors in the array.

18. The system of claim 15, wherein the controller generates signals to read out signals from the array by distinct groups of rows of pixels while the plurality of pixels are exposed to light to vary integration periods of the photodetectors in the array.
